(19) United States
(12) Patent Application Publication
(10) Pub. No.: US 2010/0153819 A1
(43) Pub. Date: Jun. 17, 2010

(54) Decoding Method and System for Low-Density Parity Check Code

(76) Inventors: Yeong-Luh UENG, Hsinchu (TW); Chung-Jay Yang, Hsinchu City (TW); Zong-Cheng WU, Yongkang City (TW)

Correspondence Address: HDLS Patent & Trademark Services, P.O. BOX 220746, CHANTILLY, VA, 20153-0746, US

(21) Appl. No.: 12/333,305

(22) Filed: Dec. 12, 2008

(51) Int. Cl. H03M 13/05; G06F 11/10

(52) U.S. Cl. 714/763; 714/752; 714/E11.032

(57) ABSTRACT

A decoding method for LDPC code includes steps of obtaining a set of parity-check matrices of a set of block codes; obtaining an identical parity-check matrix from the set of parity-check matrices; dividing the identical parity-check matrix into an odd identical parity-check matrix and an even identical parity-check matrix, wherein the odd identical parity-check matrix being composed of odd rows of the identical parity-check matrix, and the even identical parity-check matrix being composed of even rows of the identical parity-check matrix; and decoding the set of block codes basing on the odd identical parity-check matrix and the even identical parity-check matrix.

### CROSS-REFERENCE TO RELATED APPLICATIONS

This application is based upon and claims the benefit of the prior published paper, “VLSI Decoding Architecture with Improved Convergence Speed and Reduced Decoding Latency for Irregular LDPC Codes in WiMAX”, 2008 IEEE International Symposium on Circuits and Systems, pp. 520-523, May 18-21, 2008, disclosed by Yeong-Luh Ueng, Chung-Jay Yang, Zong-Cheng Wu, Chen-Eng Wu, and Yu-Lun Wang, the entire contents of which are incorporated herein by reference.

### BACKGROUND

1. Field of Invention

The present invention relates to a decoding method and system for quasi-cyclic low-density parity-check (QC-LDPC) codes. More particularly, the present invention relates to a fast-convergence decoding method and system for QC-LDPC codes.

2. Description of Related Art

Among the quasi-cyclic low-density parity-check (QC-LDPC) codes, Block-LDPC codes disclosed by H. Zhong; T. Zhang, in “Block-LDPC: A practical LDPC coding system design approach,” IEEE Transactions on Circuit and Systems-I: regular papers, Vol. 52, No. 4, pp. 766-775, April 2005, can achieve good error-correcting performance and are suitable for very-large scale integrated circuit (VLSI) implementation. The (zM_{b})×(xN_{b}) parity check matrix (PCM) of the Block-LDPC code is constructed out of z×z null matrix and cyclic shifted versions of z×z identity matrix. Layered message-passing decoding (LMPD) combined with the concepts of row grouping, column grouping, and column sum is ideally suitable for Block-LDPC codes for which a block row can be used as one horizontal layer. The LDPC codes C selected by the standard of IEEE 802.16e (WiMAX) are Block-LDPC codes.

The PCM of rate-Rc Block-LDPC (QC-LDPC) code C used in WiMAX is denoted by an M×N matrix H, where M=z×M_{b} and N=z×N_{b}. There are M_{b} block rows and N_{b} block columns in PCM H. Hence, PCM H consists of M_{b}×N_{b} sub-matrices and the dimension of each sub-matrix is z×z. The PCM H is constructed based on an M_{b}×N_{b} base matrix H_{b}. In the base matrix H_{b}, each 0 is replaced by a z×z zero sub-matrix (null matrix) and each 1 at the position (i,j) is replaced by a z×z sub-matrix (circulant matrix) that is obtained by right cyclic shifting a z×z identity matrix by p(i, j, Rc, z)≧0 columns, 0≦i≦(M_{b}−1), 0≦j≦(N_{b}−1), where the p(i, j, Rc, z) is defined in WiMAX standard. For the (2304, 1152) LDPC code, M=1152, N=2304, z=96, M_{b}=12, N_{b}=24. FIG. 1 shows the block-type PCM H of this LDPC code, where the number shown in the non-blank part at the ith row and jth column is p(i, j, Rc, z). In the block-type PCM H shown in FIG. 1, we can replace each square in the blank part and non-blank part by a z×z null matrix and non-zero circulant matrix, respectively. The circulant matrix at the ith block row and jth block column is obtained by right cyclic shifting a z×z identity matrix by p(i, j, Rc, z)≧0 columns. Note that the last 11 block columns of PCM H form a dual diagonal structure. In WiMAX, all rate-Rc LDPC codes have the same base matrix H_{b} but with different expansion factors z and different shifting indexes p(i, j, Rc, z). The shifting index p(i, j, Rc, z) can be calculated according to

$$p ( i , j , Rc , z ) = ⌊ \frac{p ( i , j , Rc , z = 96 ) z}{96} ⌋$$

In WiMAX, four code rates (Rc=1/2, 2/3, 3/4 and 5/6) and 19 code lengths (z=24, 28, 32, . . . , 96) are specified in following publication: Part 16: Air interface for fixed and mobile broadband wireless access systems amendment for physical and medium access control layers for combined fixed and mobile operation in licensed bands, IEEE P802.16e2005, 2005. Furthermore, the base matrix H_{b} and p(i, j, Rc, z=96) can be found in the same publication.

There are several ways, such as two phase message passing (TPMP) algorithm and layered message passing decoding (LMPD) algorithm, to decode Block-LDPC code defined by WiMAX. Generally, the LMPD algorithm has a smaller size of memory and a lower complexity of memory access as compared to the TPMP algorithm. In addition, the LMPD algorithm can achieve about two times faster decoding convergence as compared to the TPMP algorithm.

Since the LMPD algorithm has several advantages over the TPMP algorithm, most of the WiMAX LPDC decoders are implemented based on the LMPD algorithm.

In the TPMP algorithm, Rᵢⱼ[k] denotes the check-to-variable (C2V) message from check node i to variable node j at the kth iteration and I_{R}[i] denotes the index set of variable nodes involving check node i. Similarly, Qⱼᵢ[k] denotes the variable-to-check (V2C) message from variable node j to check node i at the kth iteration and I_{C}[j] denote the index set of check nodes involving variable node j. Let a horizontal layer be a set of rows in PCM H. In each layer, the column weight is either one or zero. The LMPD algorithm is the same as the TPMP algorithm except that the check-node operation is performed for each horizontal layer instead of whole PCM H in TPMP algorithm and the updated a posterior probability (APP) messages are passed between layers. Now we describe the operation of LMPD at the k-th iteration. For every check node i in one horizontal layer, compute Qⱼᵢ[k] corresponding to each of its variable node neighbors j, j ∈ I_{R}[i], according to (1).

Comput Rᵢⱼ[k] according to equation (2), and calculate Λⱼ[k] according to equation (3), where ΔRᵢⱼ[k]=Rᵢⱼ[k]−Rᵢⱼ[k−1]

$$\begin{matrix}{Q}_{ji} [ k ] = {Λ}_{j} [ k - 1 ] - {R}_{ij} [ k - 1 ] & ( 1 ) \\ {R}_{ij} [ k ] = {S}_{ij} [ k ] \times {min}_{{j}^{′} ∈ {I}_{R} [ i ] \backslash \{ j \}} \vert {Q}_{{j}^{′} i} [ k ] \vert & ( 2 ) \\ {Λ}_{j} [ k ] = {Q}_{ji} [ k ] + {R}_{ij} [ k ] = {Λ}_{j} [ k - 1 ] + Δ {R}_{ij} [ k ] & ( 3 )\end{matrix}$$

In general, there are two memory banks MB_{R} and MB_{Λ} used to store values of Rᵢⱼ and Λⱼ, respectively, in a LMPD-based decoder. The concept of column sum introduced in D. E Hovevar, “LDPC code construction with flexible hardware implementation”, in Proc. IEEE Int. Conf. Commu, Anchorage, Ak., pp. 2708-2712, 11-15 May 2003, is that we only need to read one value of Λⱼ[k−1], i.e., the sum of C2V messages and channel value, which is defined by λⱼ=ln(Pr(vⱼ=0|yⱼ)/Pr(vⱼ=1|yⱼ)), and one value of Rᵢⱼ[k−1] to calculate Qⱼᵢ[k] at the kth iteration. The values of Rᵢⱼ are stored in memory bank MB_{R} which is initialized with zeros. The values of Rᵢⱼ with the same i are stored in the same address of the memory bank such that we can access these values simultaneously. The memory bank MB_{Λ} is used to store the values of Λⱼ (or APP) defined in equation (3) and is initialized with λⱼ, where λⱼ is the channel value of variable node vⱼ.

Since the LDPC codes used in the WiMAX are Block-LDPC codes, we can group the parity check equations defined by one block row of PCM H as one layer in the LMPD algorithm. Since the column weight of each column in each block row (layer) of PCM H is either 0 or 1, we can use z processing units in parallel to compute messages Rᵢⱼ[k] based on the concept of row grouping used in D. E Hovevar, “LDPC code construction with flexible hardware implementation”, in Proc. IEEE Int. Conf. Commu, Anchorage, Ak., pp. 2708-2712, 11-15 May 2003. Since z check-node processing units can operate in parallel without hazards in memory access, the parallelism of such architecture is z. The number of decoding cycles is roughly the same for all z and hence the throughput is roughly proportional to z. If we use the maximum parallelism of z=96 in the decoder, then most of the hardware resource in such a decoder will be idle when we decode LDPC codes with z=24.

Accordingly, the architecture basing on either the TPMP algorithm or the LMPD algorithm has some drawbacks and somehow it can be improved.

### BRIEF SUMMARY

The present invention provides a decoding method and system for low-density parity check (LDPC) code based on a new data processing schedule to effectively decode the LDPC code.

One embodiment of the present invention provides a decoding method for LDPC code, which comprises steps of obtaining a set of parity-check matrices of a set of block codes; obtaining an identical parity-check matrix from the set of parity-check matrices; dividing the identical parity-check matrix into an odd identical parity-check matrix and an even identical parity-check matrix, wherein the odd identical parity-check matrix being composed of odd rows of the identical parity-check matrix, and the even identical parity-check matrix being composed of even rows of the identical parity-check matrix; and decoding the set of block codes basing on the odd identical parity-check matrix and the even identical parity-check matrix.

Another embodiment of the present invention provides a decoding system for LDPC code, which is adapted to decode LDPC code having a parity-check matrix that is capable of being divided into a plurality of block rows and block columns, and an identical parity-check matrix is obtained from the parity-check matrix and is capable of being divided into an odd identical parity-check matrix and an even identical parity-check matrix, wherein the odd identical parity-check matrix being composed of odd rows of the identical parity-check matrix, and the even identical parity-check matrix being composed of even rows of the identical parity-check matrix. The decoding system comprises a first memory bank, storing a plurality of posterior probability values corresponding to the block columns; a second memory bank, storing a plurality of check-to-variable messages from a plurality of check nodes to a plurality of variable nodes; and a processing apparatus, electrically coupled to the first memory bank and the second memory bank to decode a plurality of block codes of the LDPC code basing on the odd identical parity-check matrix and the even identical parity-check matrix.

The present invention divides the identical parity-check matrix into odd and even ones. Furthermore, the odd and even identical parity-check matrices are used basing on variants of LMPD algorithm such that the speed of convergence by using the present invention is faster than using the TPMP algorithm.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a figure containing conventional block-type PCM of (2304, 1152) LDPC code.

FIG. 2 is a diagram illustrating memory accessing from memory bank MB_{Λ}.

FIG. 3 is a block diagram of an LDPC decoder according to one embodiment of the present invention.

FIG. 4 is a block diagram of CVMU unit according to one embodiment of the present invention.

FIG. 5 is a block diagram of DC unit according to one embodiment of the present invention.

FIG. 6 is a scheduling diagram shown decoding procedure of LDPC code according to one embodiment of the present invention.

FIG. 7 is a scheduling diagram shown pipelining decoding of block codes according to one embodiment of the present invention.

FIGS. 8A˜8D are schematic diagrams shown the contents of several memory areas and the register files during decoding according to one embodiment of the present invention.

FIGS. 9A˜9G are schematic diagrams shown the configuration of the memory block and the contents of several memory areas and the register files according to one embodiment of the present invention.

FIG. 10 shows configuration of CVMU units according to one embodiment of the present invention.

FIG. 11 shows a timing diagram for the operation of CVMU-5/6 unit according to one embodiment of the present invention.

### DETAILED DESCRIPTION

In the following detailed description of the preferred embodiments, reference is made to the accompanying drawings which form a part hereof, and in which is shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Accordingly, the drawings and descriptions will be regarded as illustrative in nature and not as restrictive.

In one embodiment, we let Hₗ′(p) denote an M_{b}×N matrix which contains the p-th, (p+z)-th, (p+2z)-th, . . . and (p+(M_{b}−1)z)-th rows of a parity-check matrix (PCM) H, where p=0,1,2, . . . , z−1. Furthermore, let Sₗ(p) denote an index set which indicates the non-zero columns of matrix Hₗ′(p). For p=0,1,2, . . . , z−1, we delete all-zero columns of Hₗ′(p) to obtain an M_{b}×N, matrix Hₗ(p). Therefore, matrix Hₗ(p) contains the columns of Hₗ′(p) indexed by index set Sₗ(p) and |Sₗ(p)|=Nₗ. From the quasi-cyclic structure of PCM H, matrices Hₗ(p), p=0,1,2, . . . , z−1, are column-permutated versions of Hₗ≡Hₗ(0), and, for p=0,1,2, . . . , z−2,

$${S}_{l} ( p + 1 ) = {⋃}_{j = 0}^{{N}_{b} - 1} \{ \begin{matrix}q \vert q - jz = ( k + 1 - jz ) mod z ; \\ jz \leq k < ( j + 1 ) z , k ∈ {S}_{l} ( p )\end{matrix} \} \qquad ( 4 )$$

For example, Sₗ(1)={13,44,62, . . . } when Sₗ(0)={12,43,61, . . . }. We find that index sets Sₗ(p), p=0,1,2, . . . , z−1, are not the same. In addition, Sₗ(p)I [Y_{j=0,j≠p}^{z-1}Sₗ(j)]≠φ for p=0,1,2, . . . , z−1, where φ is the null set. Notably, Nₗ≠N_{b} and Nₗ<<N.

The code bits of low-density parity check (LDPC) code C indexed by the index set Sₗ(p) form a linear block code Cₗ(p). The M_{b}×Nₗ matrix Hₗ(p) is a PCM of the linear block code Cₗ(p). Since matrix Hₗ(p) is a column-permutated version of an identical parity-check matrix Hₗ, the linear block code Cₗ(p) can be decoded by using the identical parity-check matrix Hₗ. Decoding of the LDPC code C is implemented by decoding the linear block codes Cₗ(0), Cₗ(1), . . . , and Cₗ(z−1) sequentially. We first decode the linear block code Cₗ(0) using the channel (reliability) values of code bits of LDPC code C indexed by the index set Sₗ(0) and then decode the linear block code Cₗ(1) using the channel values of code bits of LDPC code C indexed by the index set Sₗ(1) and the extrinsic values provided by the decoding of the linear block code Cₗ(0) and so on. After decoding the linear block code Cₗ(z−2), we then decode the linear block code Cₗ(z−1). Such one-round decoding of the linear block codes Cₗ(p), p=0,1,2, . . . , z−1, is called one global iteration for the decoding of the LDPC code C. After decoding the linear block code Cₗ(z−1), we then re-decode the linear block code Cₗ(0) and so on. In the decoding of the linear block code Cₗ(p), we can use the extrinsic values provided by the decoding of the linear block code Cₗ(j), j≠p, since Sₗ(p)I [y_{j=0,j≠p}^{z-1}Sₗ(j)]≠φ for p=0,1,2, . . . , z−1. Since, in the decoding of the linear block code Cₗ(p), we can use extrinsic values provided by the decoding of other linear block codes Cₗ(j), j≠p, within the same global iteration, the speed of convergence of the decoding method provided in the embodiment is faster than that of the TPMP algorithm used in the prior arts.

The decoding of the linear block code Cₗ(p) by using TPMP algorithm with one iteration is called local TPMP (LTPMP), and the decoding method provided by the present invention will be described in more detail in the following paragraphs.

For the (2304, 1152) LDPC code, we find that identical parity-check matrix Hₗ has a special structure that most of columns of the identical parity-check matrix Hₗ have weight one and the weight of last 12 columns of the identical parity-check matrix Hₗ is two. In addition, the last 11 columns of the identical parity-check matrix Hₗ form a dual diagonal structure. In the embodiment, we group the rows of the identical parity-check matrix Hₗ into an even layer and an odd layer. In other words, we divide the identical parity-check matrix Hₗ into two matrices, including an odd identical parity-check matrix Hₒ and an even identical parity-check matrix Hₑ, each of which is of dimension (M_{b}/2)×Nₗ and is consists of the odd rows and even rows of the identical parity-check matrix Hₗ, respectively. Due to the dual diagonal structure of the identical parity-check matrix Hₗ, extrinsic values obtained in the decoding of the linear block code Cₗ(p) based on the even identical-parity check matrix Hₑ (or the odd identical-parity check matrix Hₒ) can be used in the decoding of the linear block code Cₗ(p) based on the odd identical-parity check matrix Hₒ (or the even identical-parity check matrix Hₑ). Since most of columns of the odd and even identical-parity check matrix Hₒ and Hₑ have weight one, such a decoding is an efficient implementation of LMPD algorithm of the linear block code Cₗ(p). Such a kind of LMPD algorithm of linear block code Cₗ(p) with one iteration is called even-odd message passing decoding (EO-MPD). The cases of 1.5 and 2 iterations are called EOE-MPD and EOEO-MPD, respectively. In other words, the EOE-MPD of the linear block code Cₗ(p) is implemented by sequentially using the even identical-parity check matrix Hₑ, the odd identical-parity check matrix Hₒ, and the even identical-parity check matrix Hₑ again. Among these three methods, the EO-MPD (EOEO-MPD) method can achieve the worst (best) error performance but needs the smallest (largest) number of check-node operations defined in the equation (2) stated above.

Because the EO-MPD method proposed by the present invention is an LMPD-based decoding algorithm, using the EO-MPD method to decode the linear block code Cₗ(p) achieves better error performance as compared with using LTPMP algorithm although the error performance of decoding the linear block code Cₗ(p) by using the EO-MPD method is the worst in the three proposed decoding methods.

We illustrate the decoding architecture by using the (2304,1152) LDPC code and EOE-MPD in following paragraphs.

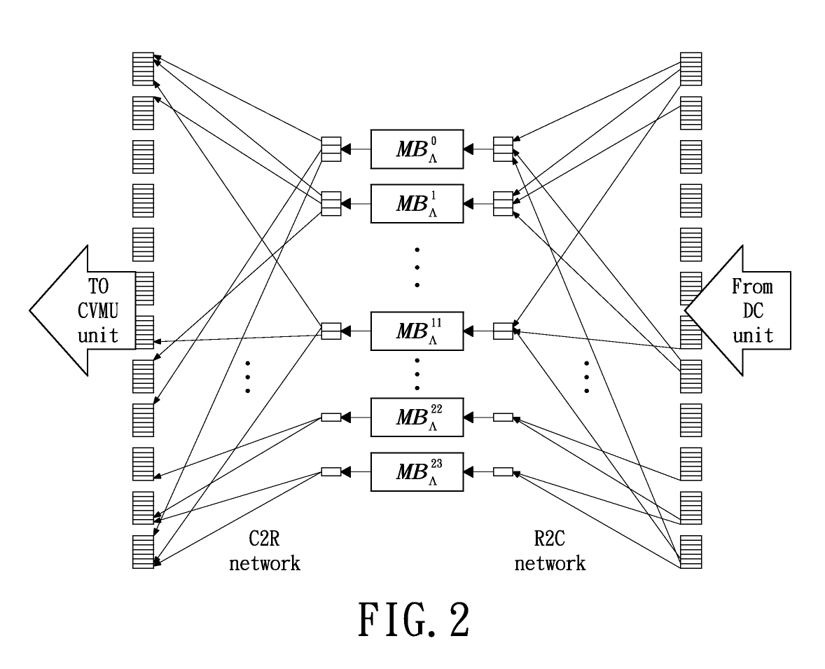

Let B_{Λ} and B_{R} be the number of bits used to represent Λⱼ and Rᵢⱼ, respectively. The APP memory bank MB_{Λ} consists of N_{b} blocks of z×B_{Λ} memory which are denoted by MB_{Λ}₀, j=0, 1, . . . N_{b}−1. The memory block MB_{Λ}^{j} is implemented by using single-port FIFOs. Each block of memory can be used to store values of Λⱼ corresponding to one block column of the PCM H. The values of Λⱼ, j=0, 1, . . . ,z−1, are stored in the memory block MB_{Λ}⁰, the values of Λ_{j-z}, j=0, 1, . . . , z−1, are stored in the memory block MB_{Λ}¹, and so on. In the decoding of Cₗ(p), p=0, 1, . . . , z−1, we must access Λⱼ, j ∈ S₁(p), from the memory bank MB_{Λ}. FIG. 2 shows how to read (write) Λⱼ from (into) the memory bank MB_{Λ} through C2R (R2C) network. The number of edges of C2R (R2C) network is equal to the number of ones in the identical PCM Hₗ. Recall that the number of ones in the identical PCM Hₗ is much less than that in the PCM H. For (2304,1152) LDPC code, there are 76 ones and 7296 ones in the identical PCM Hₗ and the PCM H, respectively. Hence, the routing complexity of C2R (R2C) network is significantly reduced in the proposed architecture.

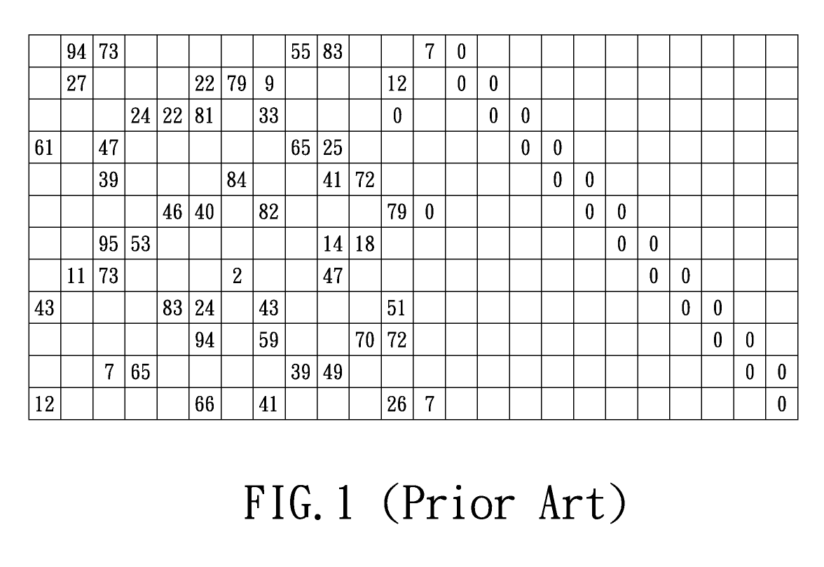

The proposed decoding of C is implemented by sequentially decoding linear block codes Cₗ(0), Cₗ(1), . . . , Cₗ(z−1) with {Λⱼ|j ∈ Sₗ(0)}, {Λⱼ|j ∈ Sₗ(1)}, . . . , {Λⱼ|j ∈ Sⱼ(z−1)}, respectively. Recall that Sₗ(p+1) is the quasi-cyclic version of Sₗ(p) and the relationship between Sₗ(p+1) and Sₗ(p) is given in above equation (4). From the PCM H shown in FIG. 1, we can obtain Sₗ(0)={12, 43, 61, . . . }. With equation (4) and Sₗ(0), we can obtain S₍1) ={13, 44, 62, . . . }. Similarly, we can obtain Sₗ(p), p=2, 3, . . . ,z−1. Note that Λⱼ indexed by the first three elements in each Sₗ(p), p=0, 1, . . . , z−1, are stored in the memory block MB_{Λ}⁰.

Since the largest row weight of the PCM H is 7, a memory bank MB_{R}, which is initialized with zeros, consists of M_{b} blocks of z×(7B_{R}) memory and is used to store the values of the messages Rᵢⱼ. The memory bank MB_{R} is implemented by single-port register files. Since the messages Rᵢⱼ is stored properly, only one cycle is needed to read (write) values of the messages Rᵢⱼ corresponding to the i^{th} row from (into) the memory bank MB_{R}.

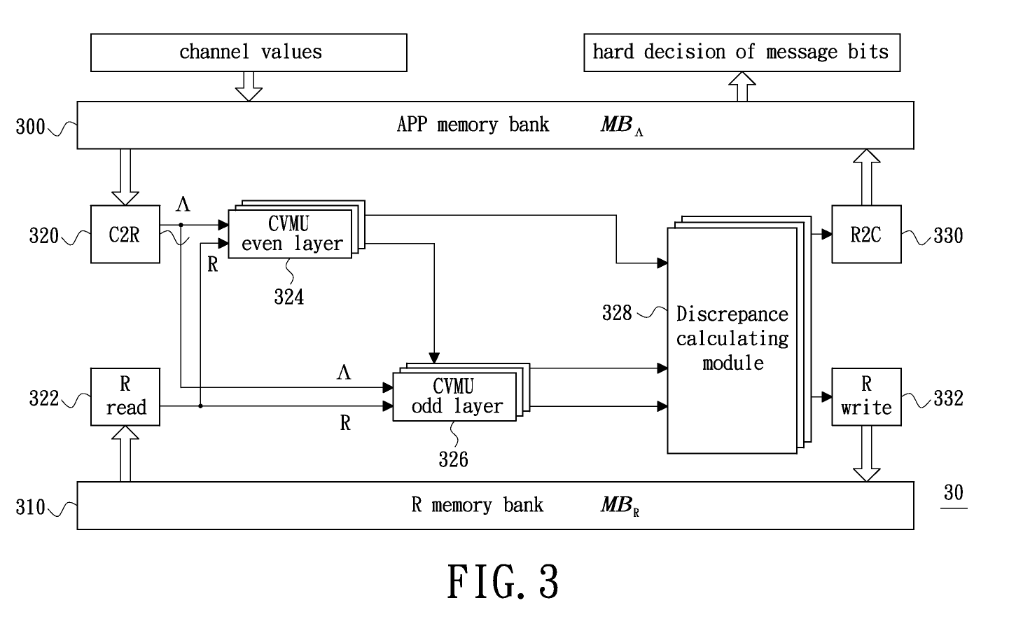

Recall that EOE-MPD utilizes the properties that the weight of last 12 columns of the identical PCM Hₗ is 2, and the last 11 columns of the identical PCM Hₗ form a dual diagonal structure to increase the speed of convergence. We use the decoding architecture in FIG. 3 to implement the EOE-MPD of linear block codes Cₗ(p), p=0, 1, . . . ,z−1, efficiently. The decoder 30 in FIG. 3 is used to sequentially decode the linear block codes Cₗ(0), Cₗ(1), . . . , Cₗ(z−1). For each check node i of the identical PCM Hₗ, we divide set I_{R}[i] into sets I_{A}[i] and I_{B}[i], where I_{B}[i] includes the last two variable nodes (code bits) of the identical PCM Hₗand I_{A}[i]≡I_{R}[i]\I_{B}[i]. Let I_{BT}=Yᵢ₌₀^{M}^{_{b}}⁻¹I_{B}[i] It can be checked that |I_{BT}=12 for the (2304, 1152) LDPC code.

For each variable node j ∈ I_{BT}, we have Λⱼ[k]=λ_{J}+Rᵢⱼ[k]+R_{i′j}[k], where i, i′ ∈ I_{C}[j]. In addition, i is an even number if i′ is an odd number. Hence, we can calculate channel value λⱼ according to λⱼ=Λⱼ[k]−Rᵢⱼ[k]−R_{i′j}[k]. Since most of columns of the even identical parity-check matrix Hₑ have weight one, M_{b}/2 CVMU (check-to-variable message update) units denoted by CVMU. Even Layer 324 are used in parallel to calculate m1A=min_{j′∈I}_{_{A}}_{[i]}|Q_{j′i}[k]|≡|Qⱼ_{_{m1A}}ᵢ[k]|, m2A=min_{j′∈I}_{_{Λ}}_{[i]\{j}_{_{m1A}}_{}}|Q_{j′i}[k]|≡|Qⱼ_{_{m2A}}ᵢ[k]|, j_{m1A}, j_{m2A}, and Rᵢⱼ[k], j ∈ I_{B}[i], based on even rows i or the identical PCM Hₗ, i.e., the even identical parity-check matrix Hₑ. For all j ∈ I_{BT}, we calculate V2C message Q_{ji′}[k] by Qⱼᵢ′[k]=λⱼ+Rᵢⱼ[k], where i, i′ ∈ I_{C}[j]. Note that i′ is odd and j ∈ I_{B}[i′]. Similarly, we can obtain m1=min_{j′∈I}_{_{R}}_{[i′]|Q}_{j′i′}[k]|≡|Qⱼ_{ₘ₁}_{i′}[k], m2=min_{j′∈I}_{_{R}}_{[i′]\{j}_{ₘ₁}_{}}|Q_{j′i′}[k]|≡|Qⱼ_{ₘ₂}_{i′}[k]|, jₘ₁, iₘ₂, and R_{i′j}[k], j ∈ I_{B}[i′] based on odd rows i′ of the identical PCM Hₗ, i.e., the odd identical parity-check matrix Hₒ, by using the other M_{b}/2 CVMU units denoted by CVMU Odd Layer 326 in FIG. 3.

Note that a CVMU module comprises the CVMU Odd Layer 326 and CVMU Even Layer 324. A part of the CVMU module is used to calculate and output a plurality of first-type variable-to-check messages from one of the variable nodes, which corresponds to one column of the even identical parity-check matrix, to the check nodes corresponding to odd rows of the identical parity-check matrix Hₗ. Another part of the CVMU module is used to calculate and output a plurality of second-type variable-to-check messages from one of the variable nodes, which corresponds to one column of the odd identical parity-check matrix, to the check nodes corresponding to even rows of the identical parity-check matrix Hₗ.

For all j ∈ I_{BT}, we calculate V2C message Qⱼᵢ[k] by Qⱼᵢ[k]=λⱼ+R_{i′j}[k], where i, i′ ∈ I_{C}[j]. Note that i is even and j ∈ I_{B}[i]. Since the last several columns of the identical PCM Hₗ forms a dual diagonal structure, Qⱼᵢ′(Qⱼᵢ) for the variable nodes in I_{B}[i′] (I_{B}[i]) obtained in the decoding of the linear block code Cₗ(p) based on the even identical parity-check matrix Hₑ (the odd identical parity-check matrix Hₒ) can be used in the decoding of Cₗ(p) based on the odd identical parity-check matrix Hₒ (the even identical parity-check matrix Hₑ). The outputs of these CVMU units 324 and 326 are fed to the unit of discrepancy calculating module (DC) 328 to calculate Rᵢⱼ and ΔRᵢⱼ.

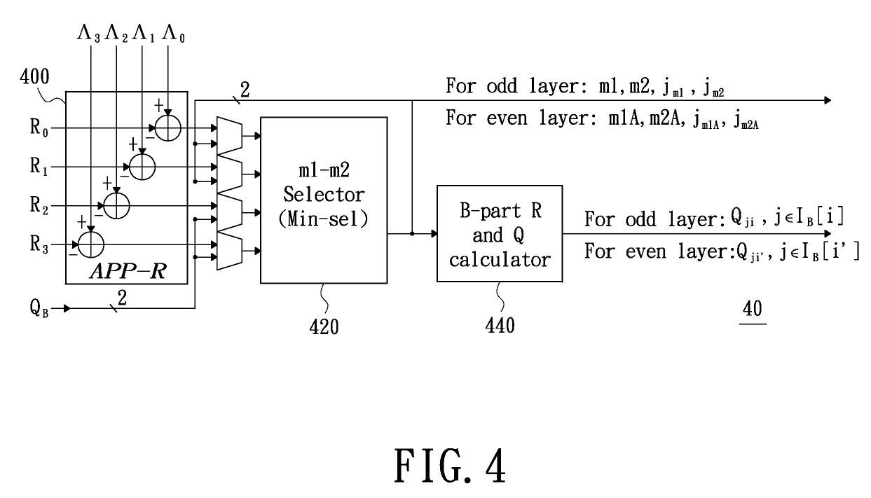

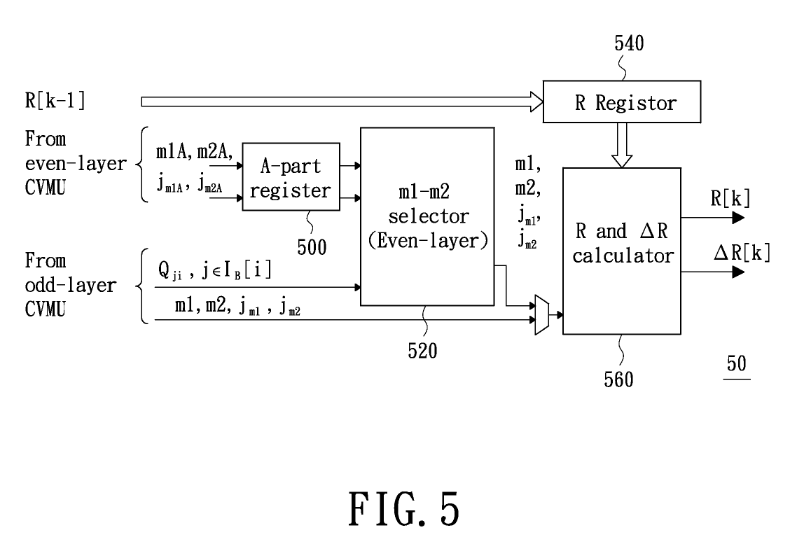

FIG. 4 and FIG. 5 show the block diagrams of CVMU unit and DC unit, respectively. A CVMU unit 40 consists of modules of APP-R 400, m1-m2 selector 420, and B-part R and Q calculator 440. A DC unit 50 consists of A-part register 500, R register 540, m1-m2 selector 520 and R and ΔR calculator 560.

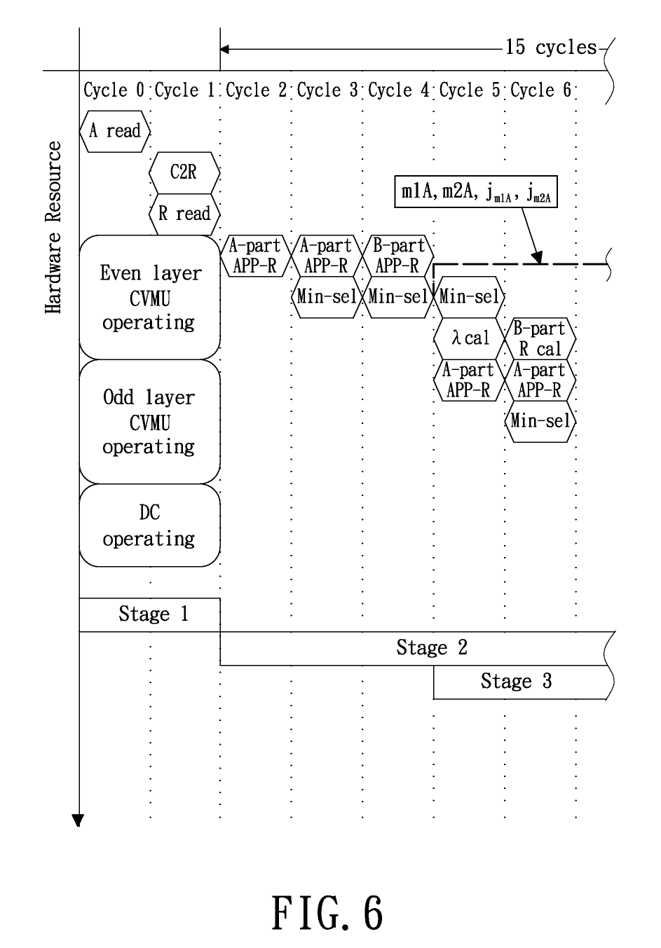

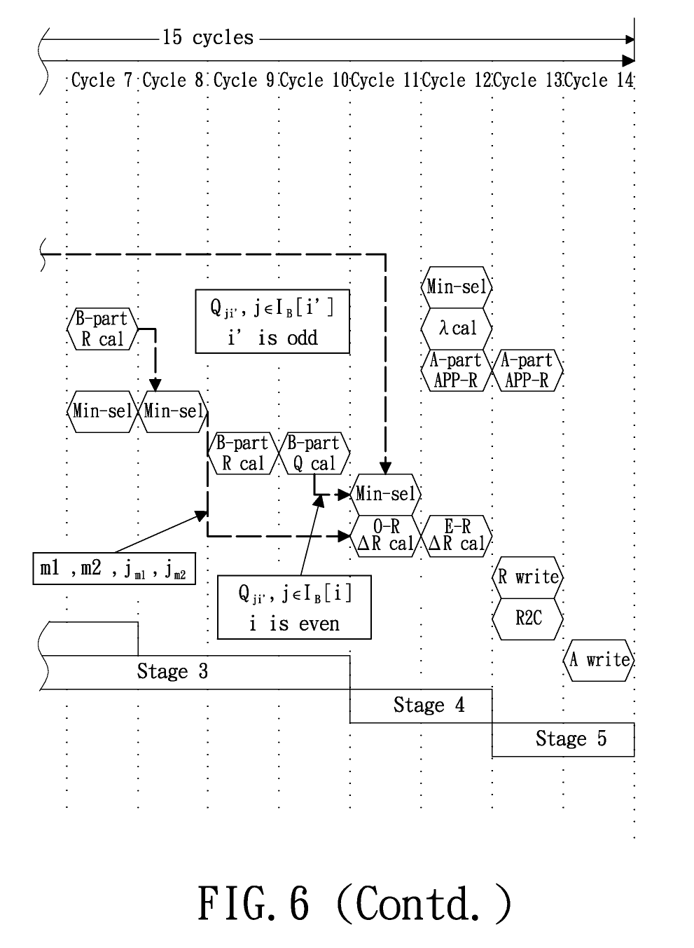

The detail scheduling is shown in FIG. 6 and is described as follows.

Stage 1: Read the associated values of Λⱼ[k−1] from the APP memory bank MB_{Λ} 300 at Cycle 0 and arrange the associated values of Λⱼ[k−1] in a row-based form by using the column-to-row module (C2R) 320 at Cycle 1. At Cycle 1, we also read the associated values of Rᵢⱼ[k−1]and R_{i′j}[k−1] from the R memory bank MB_{R} 310 by using the check-to-variable message reading module (R read) 322.

Stage 2: For each even row i in the identical PCM Hₗ and each variable node j ∈ I_{R}[i], compute Qⱼᵢ[k] according to equation (1) presented above by using the module of APP-R 400 at Cycles 2, 3, and 4. Then, use the module of m1-m2 selector 420 to calculate m1A, m2A, j_{m1A}, and j_{m2A} at Cycle 4. The values of m1A, m2A, j_{m1A}, and j_{m2A} are stored in the A-part-register 500 of the DC unit 50 for later usage. At Cycle 5, we calculate m1, m2, jₘ₁, and jₘ₂ by using the module of m1-m2 selector 420. These operations are performed in the step of “Min-sel” at Cycles 3, 4, and 5. At Cycle 5, we also calculate λⱼ=Λⱼ[k−1]−Rᵢⱼ[k−1]−R_{i′j}[k−1]=Qⱼᵢ[k]−R_{i′j}[k−1] for each variable node j ∈ I_{B}[i] by using the module of APP-R 400, where i′ ∈ I_{C}[j]. This operation is performed in the step of “λ cal” of FIG. 6. Note that all the values of λⱼ, j ∈ I_{B}[i′], which will be used in Stage 3 are also produced in this step. At Cycles 6 and 7, use the module of B-part R and Q calculator 440 to calculate Rᵢⱼ[k], j ∈ I_{B}[i], according to equation (2) and then calculate Qⱼᵢ′[k]=λⱼ+Rᵢⱼ[k], i ∈ I_{C}[j], for all j ∈ I_{B}[i′]. Note that the values of Rᵢⱼ[k] for j ∈ I_{A}[i] are not calculated in this stage.

Stage 3: For each odd row i′ of the identical PCM Hₗ and each variable node j ∈ I_{A}[i′], compute Qⱼᵢ′[k] at Cycles 5 and 6. At Cycle 8, calculate m1, m2, jₘ₁, and jₘ₂ by using Qⱼᵢ′[k], j ∈ I_{Λ}[i′], obtained in this stage and Qⱼᵢ′[k], j ∈ I_{B}[i′], obtained in Stage 2. Calculate R_{i′j}[k], j ∈ I_{B}[i′] at Cycle 9. Then calculate Qⱼᵢ[k]=λⱼ+R_{i′j}[k], j ∈ I_{C}[j], for all j ∈ I_{B}[i] at Cycle 10.

Stage 4: This stage involves the operations of DC unit 50 shown in FIG. 5. For each odd row i′ in the identical PCM Hₗ, use the module of R and ΔR calculator 560 in the DC unit 50 with the m1, m2, jₘ₁, and jₘ₂ obtained in Stage 3 to calculate R_{i′j}[k] and ΔR_{i′j}[k]=R_{i′j}[k]−R_{i′j}[k−1] for all j ∈ I_{R}[i′] at Cycle 11. Similarly, for each even row i in the identical PCM Hₗ, use the module of m1-m2 selector 520 in the DC unit 50 with the m1A, m2A, j_{m1A}, and j_{m2A} stored in the A-part register 500, and Qⱼᵢ[k], j ∈ I_{B}[i], obtained in Stage 3 to update m1, m2, jₘ₁, and jₘ₂ at cycle 11 and then calculate Rᵢⱼ[k] and ΔRᵢⱼ[k]=Rᵢⱼ[k]−Rᵢⱼ[k−1] for all j ∈ I_{R}[i] at Cycle 12.

Stage 5: Write the associated values of Rᵢⱼ[k] and R_{i′j}[k] to the R memory bank MB_{R} 310 directly by using the check-to-variable message writing module (R write) 332 at Cycle 13. For calculating Λⱼ[k], arrange the associated values of ΔRᵢⱼ[k] and ΔR_{i′j}[k] in a column-based form by using the row-to-column module (R2C) 330 at Cycle 13. At Cycle 14, calculate Λⱼ[k] by Λⱼ[k]=Λⱼ[k−1]+R_{i″j}[k], for each variable node j ∈ I_{A}[i″], where i″ ∈ I_{C}[j] We also calculate Λⱼ[k] by Λⱼ[k]=Λⱼ[k−1]+ΔRᵢⱼ[k]+ΔR_{i′j}[k] for each variable node j ∈ I_{B}[i], where i′ ∈ Ic[j].

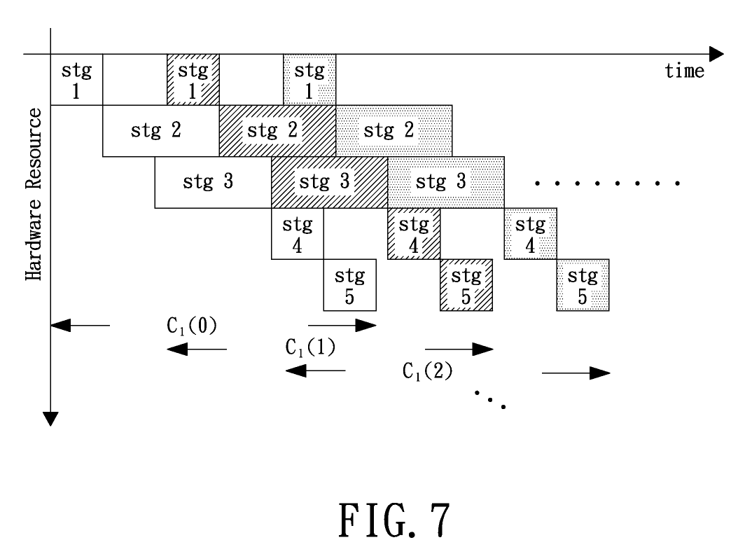

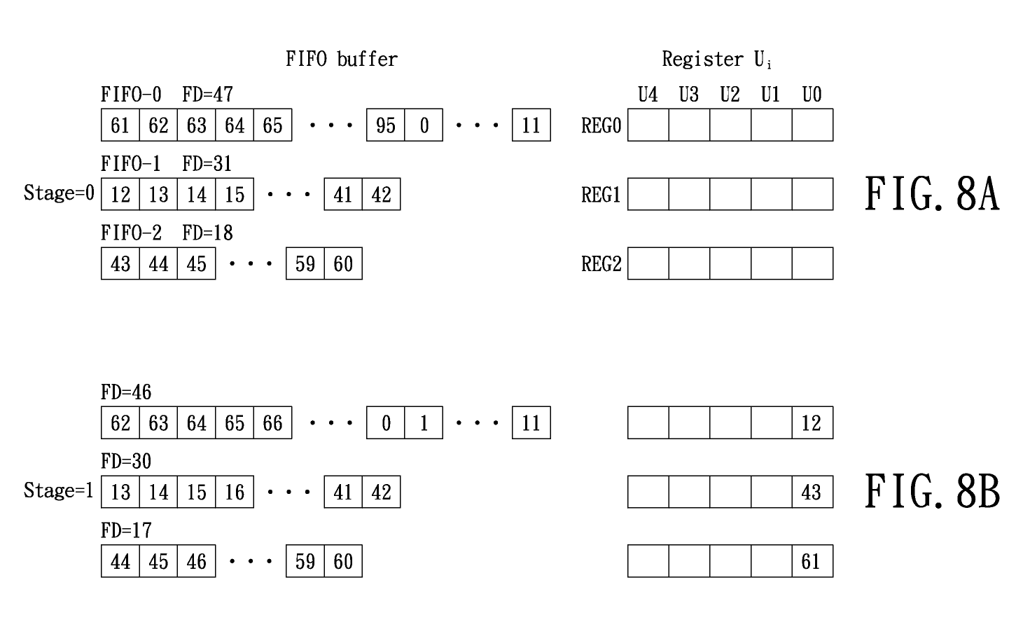

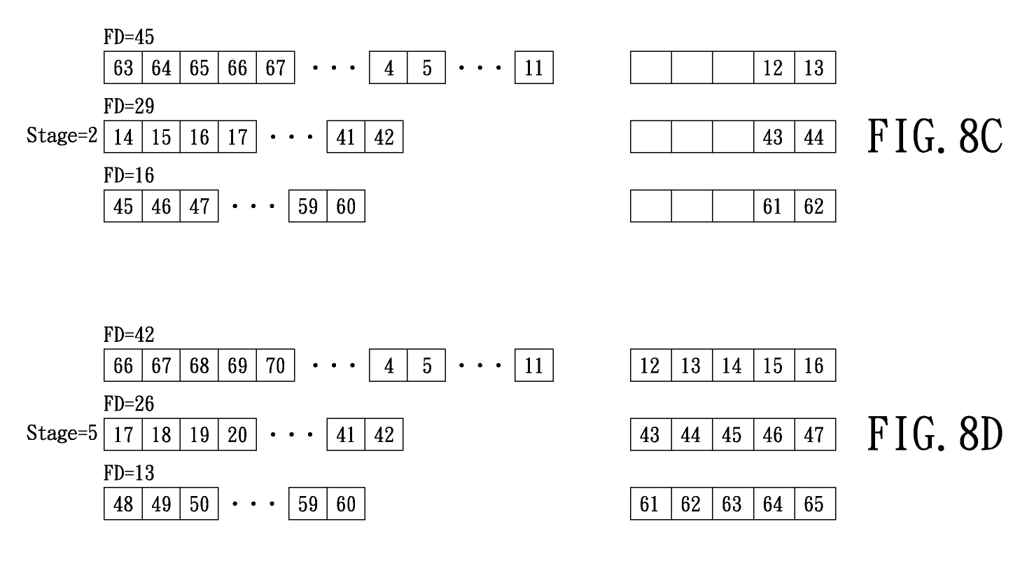

To increase the throughput, in C. P. Fewer, M. F. Flanagan, and A. D. Fagan, “A versatile variable rate LDPC codec architecture,” IEEE Trans. Circuits Syst. I, Reg. Papers, vol. 54, no. 10, pp. 2240-2250, October 2007, the authors proposed to decode two code-words at the same time without hazards in memory access. In the present invention, we propose a five-stage pipeline architecture for which the scheduling is shown in FIG. 7 to increase the throughput. To support such a pipeline architecture, the memory access from the memory bank MB_{Λ} should be modified accordingly. Since it takes five decoding stages to obtain ΔRᵢⱼ[k] for calculating Λⱼ[k], we need several five-stage registers to store Λⱼ[k−1] in MB_{Λ}. Hence, five-stage registers should be used. The register at stage-i is denoted by Ui, i=0, 1, . . . , 4. FIG. 8A to D show the contents of several memory areas, which is obtained by dividing one of the memory blocks in the memory bank, and the register files during decoding. The memory areas are composed of FIFOs in the embodiment and are referred as FIFOs hereinafter. Furthermore, each register file comprises at least one register. Originally, the lengths of FIFO-0, FIFO-1, and FIFO-2 are 47(12−61+96), 31(43−12), and 18(61-43), respectively. At Stage 0, Λ₆₁[k−1], Λ₁₂[k−1], and Λ₄₃[k−1] required for the decoding of linear block code C₁(0) are read from FIFO-0, FIFO-1, and FIFO-2, respectively. Λ₆₁[k−1], Λ₁₂[k−1], and Λ₄₃[k−1] are also stored in U0 of REG2, REG0, and REG1 at Stage 1, respectively. At Stage 2, Λ₆₁[k−1], Λ₁₂[k−1], Λ₄₃[k−1] are shifted to U1 since Λ₆₂[k−1], Λ₁₃[k−1], and Λ₄₄[k−1] which are required for the decoding of linear block code Cₗ(1) must be read from the FIFOs and should be stored in the registers U0. At Stage 5, Λ₆₁[k−1], Λ₁₂[k−1], and Λ₄₃[k−1] are at “U4” and are added with the corresponding discrepancies of C2V messages, i.e., ΔR, to produce Λ₆₁[k], Λ₁₂[k], and Λ₄₃[k], which are written into FIFO-2, FIFO-0, and FIFO-1, respectively.

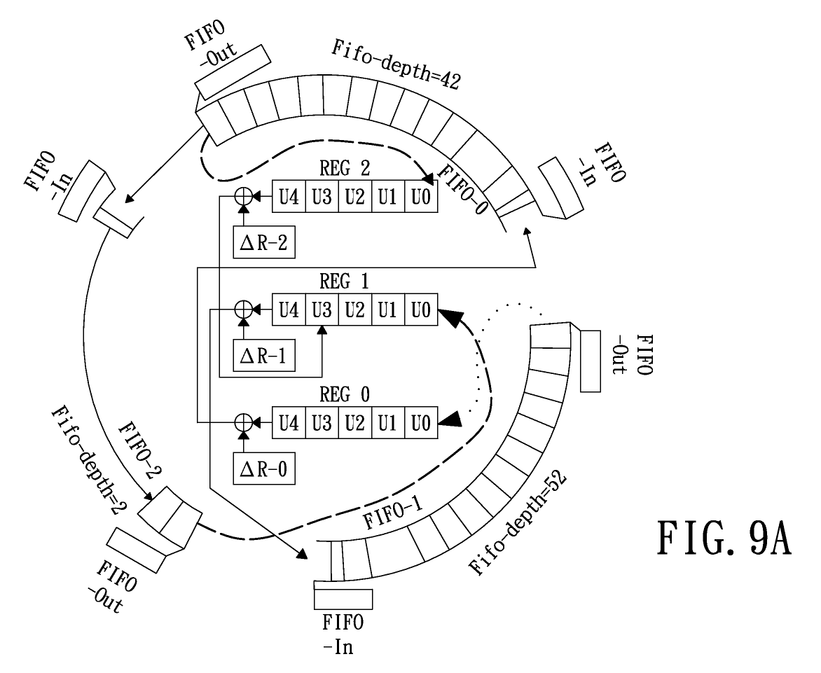

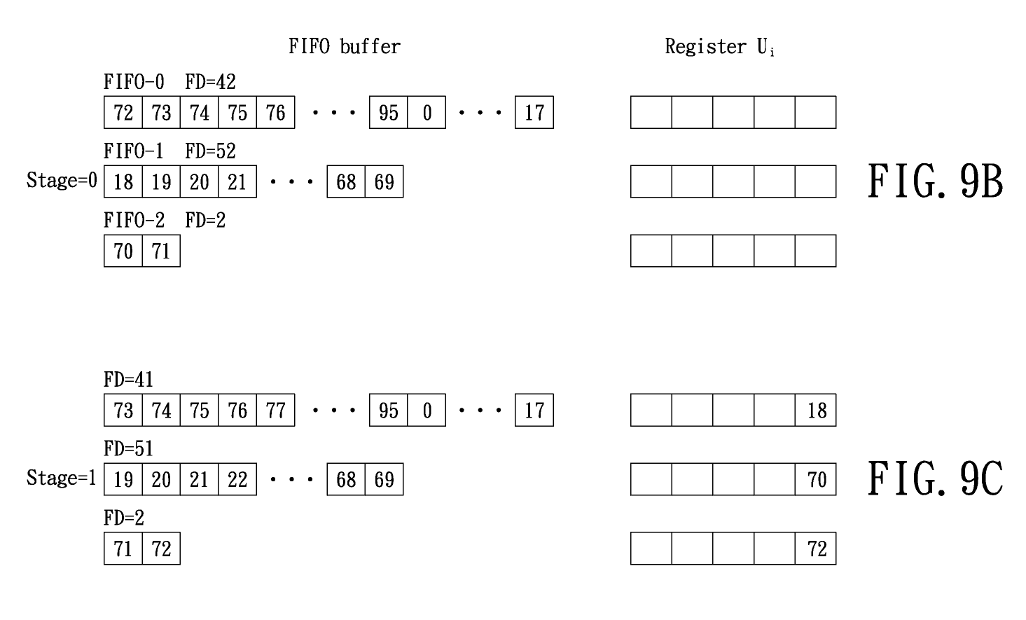

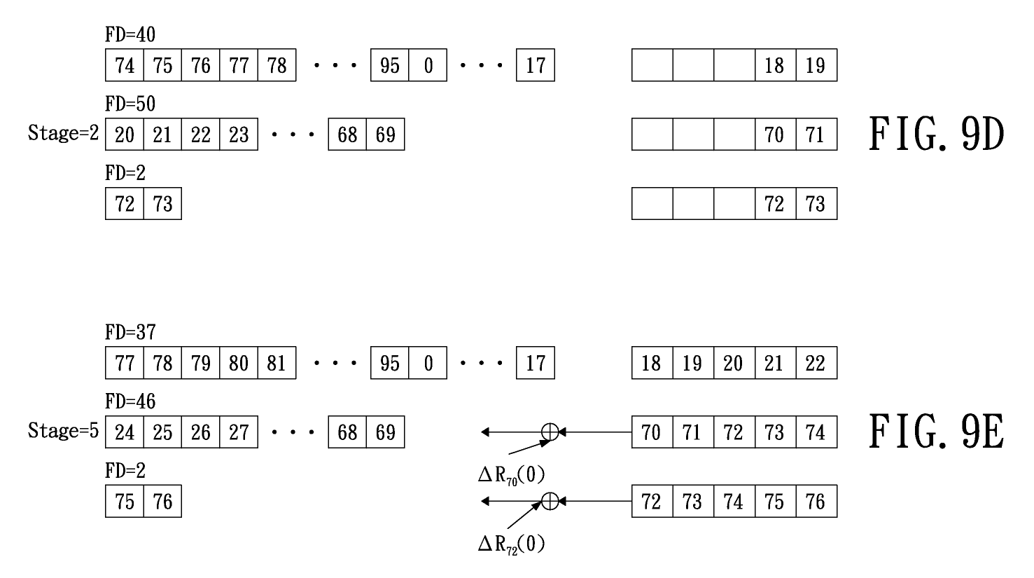

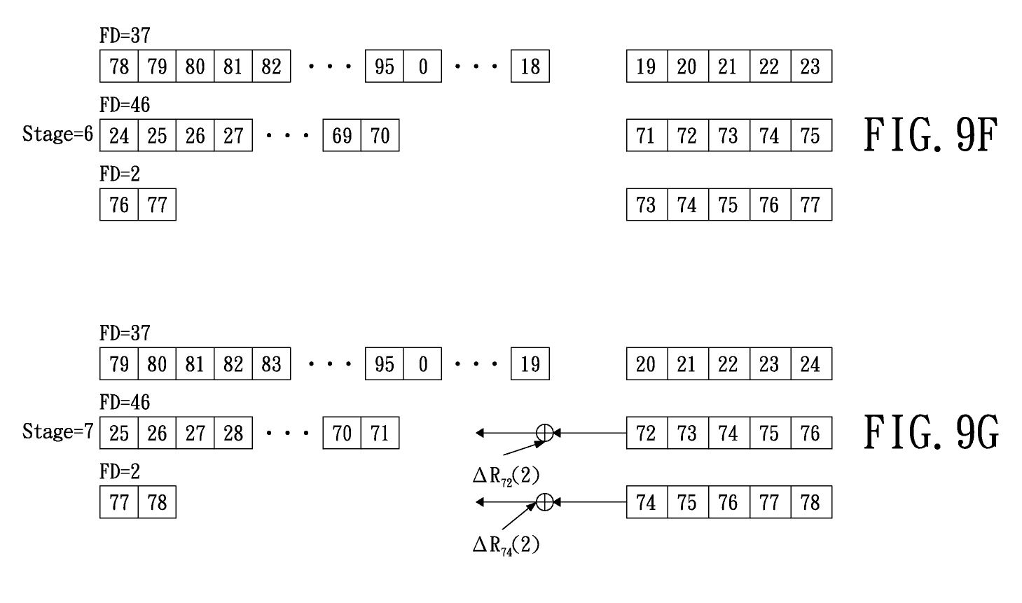

Since all of the lengths of FIFO-0, FIFO-1, and FIFO-2 in the memory block MB_{Λ}₀ are greater than 5, these FIFOs are not empty during the five-stage pipeline decoding. Hence, there is no memory-access hazard in the memory block MB_{Λ}₀. Now consider the case of the memory block MB_{Λ}¹⁰ for which there are hazards in memory access. Originally, the lengths of FIFO-0, FIFO-1, and FIFO-2 in the memory block MB_{Λ}¹⁰ are 42, 52, and 2, respectively. The length of FIFO-2 is shorter than 5. It means that FIFO-2 will be empty during the pipeline decoding. In addition, we must update the APP of some variable nodes, i.e. Λⱼ, twice within the five decoding stages. For this problem, we propose a solution which is described as follows. FIG. 9A shows the configuration of the memory block MB_{Λ}¹⁰. The configuration of the memory block MB_{Λ}¹⁰ is the same as that of the memory block MB_{Λ}⁰ except for the following differences. In both the memory block MB_{Λ}⁰ and MB_{Λ}¹⁰, the inputs of FIFO-0 and FIFO-1, are from the outputs of REG0 and REG1, respectively. However, to avoid the occurrence of empty FIFO-2 during the pipeline decoding, in the memory block MB_{Λ}¹⁰, the input of FIFO-2 is from the output of FIFO-0 instead of REG2. In both the memory block MB_{Λ}⁰ and MB_{Λ}¹⁰ the inputs of REG0, REG1, and REG2 are from FIFO-1, FIFO-2, and FIFO-0, respectively. However, there is an input for U3 of REG1 in the memory block MB_{Λ}¹⁰. With such a configuration, we can regard U0, U1, and U2 of REG1 as extended buffers for FIFO-2 during the five-stage decoding. Based on the configuration shown in FIG. 9A, we can obtain the contents of the FIFOs and registers during decoding which are shown in FIGS. 9B to 9G. At Stage 0, Λ₇₂[k−1] is read from FIFO-0. At Stage 1, Λ₇₂[k−1] is stored in FIFO-2 to avoid the occurrence of empty FIFO-2 and in U0 of REG2. Λ₇₂[k−1] is read from FIFO-2 at Stage 2 and stored in U0 of REG1 at Stage 3. At Stage 5, ΔR corresponding to Λ₇₂, i.e., ΔR₇₂(0), is available and is added with Λ₇₂[k−1] to produce temporary APP Λ₇₂[k]. This temporary APP Λ₇₂[k] is written into U3 of REG1 at Stage 6. At Stage 7, new ΔR corresponding to Λ₇₂, i.e., ΔR₇₂(2), is available which is added with temporary APP Λ₇₂[k] to produce the final APP Λ₇₂[k].

Recall that there are four code rates (R_{c}=1/2, 2/3, 3/4, and 5/6) and 19 code lengths (N=576, 672, 768, . . . , 2304) specified in WiMAX. The size of sub-matrix can be from 24×24 to 96×96. The dimensions of the base matrix H_{b -}and the PCM H for a rate-R_{c} LDPC code is [(1−R_{c})24]×24 and [(1−R_{c})24z]×[24z], respectively. The possible degrees of variable nodes (or column weights of the PCM H) are 2, 3, 4, and 6. The maximum degrees of check nodes (or row weights of the PCM H) are 7 and 20 for rate-1/2 and rate-5/6 LDPC codes, respectively. Design a decoding architecture to support such a high number of defined codes in WiMAX is a big challenge. Now we show how to modify the presented pipeline architecture to support the LDPC codes in WiMAX specified by parameters of R_{c} and z.

If the memory bank MB_{R} and MB_{Λ} are configured properly, the decoding architecture described above for the (2304, 1152) LDPC code (z=96) can support other rate-1/2 LDPC codes given in WiMAX. Modification of the computational part, i.e, CVMU units, is not needed. It is obvious that the memory bank MB_{R} used in the (2304, 1152) LDPC decoder can support other rate-1/2 LDPC codes. Now we show how to configure the memory bank MB_{Λ} to support other rate-1/2 LDPC codes. Let I_{C}(j,R_{c})={i₀,i₁, . . . , i_{d}_{ᵥ}_{(j,R}_{_{c}}₎₋₁} be an index set which indicates nonzero rows of the jth column of base matrix H_{b} for rate-R_{c} LDPC codes, where dᵥ(j, R_{c}) is the column weight of the jth column of the base matrix H_{b}. This implies that p(i, j, R_{c}, z)≧0 for all i ∈ I_{C}(j, R_{c}). Since all LDPC codes with the same rate R_{c} have the same base matrix H_{b}, the number of FIFOs in each memory block MB_{Λ}^{j} is the same for all possible code lengths (or z). Suppose p(i₀,j,R_{c},z)>p(i₁,j,R_{c},z)> . . . >p(i_{d}_{ᵥ}_{(j,R}_{_{c}}₎,j,R_{c},z). In MB_{Λ}^{j} of this LDPC code, the number of FIFOs is dᵥ(j, R_{c}) and the lengths of FIFOs are [p(i₀,j,R_{c},z)−p(i₁,j,R_{c},z)], [p(i₁,j,R_{c},z)−p(i₂, j,R_{c},z)], . . . , [p(i_{d}_{ᵥ}_{(j,R}_{_{c}}₎₋₂,j,R_{c},z)−p(i_{d}_{ᵥ}_{(j,R}_{_{c}}₎₋₁,R_{c},z)], [p(i_{d}_{ᵥ}_{(j,R}_{_{c}}₎₋₁,j,R_{c},z)−p(i₀,j,R_{c},z)+z]. According to

$$p ( i , j , Rc , z ) = ⌊ \frac{p ( i , j , Rc , z = 96 ) z}{96} ⌋$$

and p(i,j,R_{c},z=96), we find that if we choose the size of each FIFO based on z=96, then these FIFOs can be configured to support other z by slightly modifying the APP access unit.

For multi-rate capability, we do the following modifications in the memory banks MB_{Λ} and MB_{R}. The number of FIFOs in each MB_{Λ}^{j} should be max_{R}_{_{c}} dᵥ(j,R_{c}) and the length of each memory areas (FIFO in the above embodiment) in each memory block MB_{Λ}^{j} may be increased to meet the requirement for all these code rates. Recall that the memory bank MB_{R} consists of 12 blocks of z×(7B_{R}) in the (2304, 1152) LDPC decoder. For multi-rate capability, the memory bank MB_{R} consists of 12 blocks of z×(8B_{R}) memory instead of z×(7B_{R}) memory. In a rate-1/2 LDPC decoder, the ith block of z×(8B_{R}) memory is used to store C2V messages corresponding to the ith block row of the PCM H. In a rate-5/6 LDPC decoder, the ith, (i+1)th, and (i+2)th blocks of z×(8B_{R}) memory are used to store C2V messages corresponding to the ith block row of the PCM H. Based on a similar approach, we can configure the memory bank MB_{R} to support rate-2/3 and rate-3/4 LDPC codes. In our multi-rate and multi-size decoder, the memory bank MB_{Λ} consists of 24 memory blocks, where each memory block consists of 2 to 6 memory areas, and the memory bank MB_{R} consists of 12 blocks of 96×40 memory.

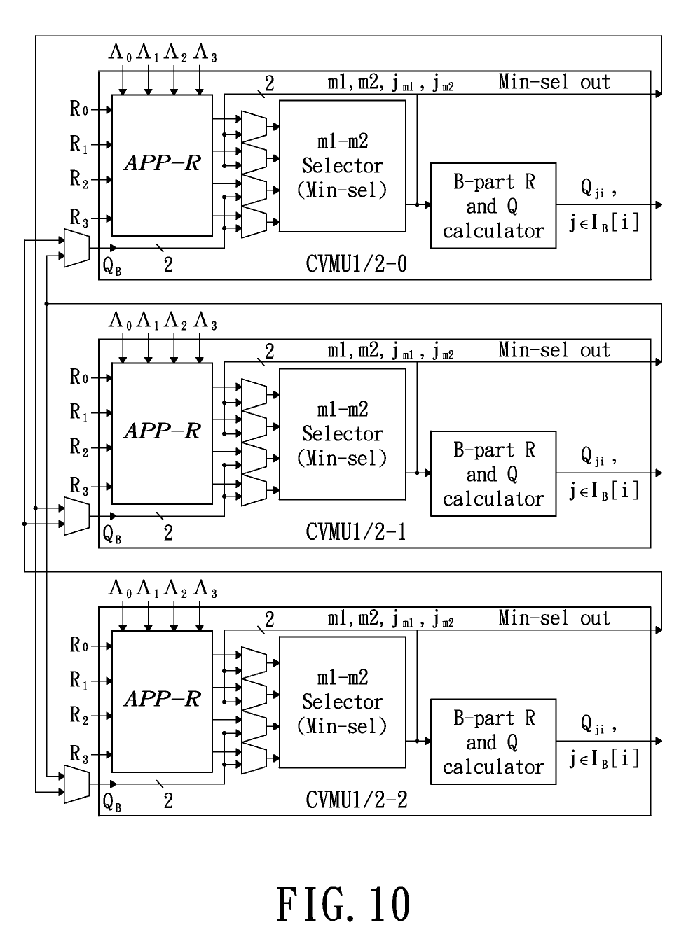

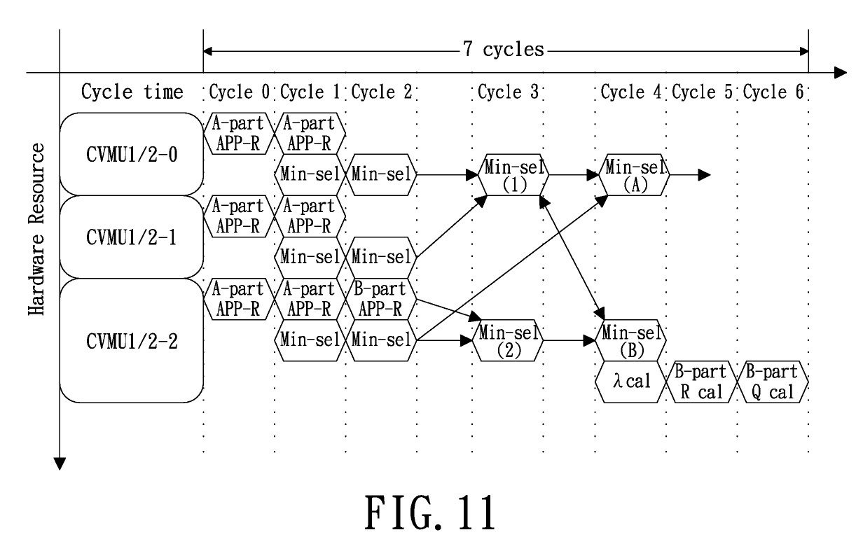

Now we show how to configure the CVMU units used in the rate-1/2 LDPC decoder to support rate-5/6 LDPC decoders. Recall that a CVMU unit is responsible for the calculation of C2V messages associated with one row of the identical PCM Hₗ. Since the number of rows of the identical PCM Hₗ equals 12 and 4 for rate-1/2 and rate-5/6 LDPC codes, respectively, there are 12 CVMU units (CVMU-1/2 unit) and 4 CVMU units (CVMU-5/6 unit) used to decode rate-1/2 and rate-5/6 LDPC codes, respectively. We can combine 3 CVMU-1/2 units to form a CVMU-5/6 unit since the maximum row weights of the identical PCM Hₗ for rate-1/2 LDPC codes and rate-5/6 LDPC codes are 7 and 20, respectively. The configuration of CVMU units and the timing diagram for the operation of CVMU-5/6 unit are shown in FIG. 10 and FIG. 11, respectively. Suppose the weight of the i^{th} row of the identical PCM Hₗ is 20. We divide the values of |Qⱼᵢ| corresponding to the first 18 nonzero elements of the ith row of the identical PCM Hₗ into three groups with equal size. The values of |Qⱼᵢ| corresponding to the last 2 nonzero elements of the ith row of the identical PCM Hₗ are classified into the fourth group. Let Γₖ be the set of |Qⱼᵢ| corresponding to the kth group, where k=1, 2, 3, 4. At Cycle 2 in FIG. 11, the outputs of CVMU1/2-k are the minimum and second minimum among all the |Qⱼᵢ| ∈ Γₖ, where k=1, 2, 3. At Cycle 3, we obtain the minimum (and second minimum) among all the |Qⱼᵢ| ∈ Γ₁ ∪ Γ₂ in the step of “Min-sel (1)” and obtain the minimum (and second minimum) among all the |Qⱼᵢ| ∈ Γ₃ ∪ Γ₄ in the step of “Min-sel (2)”. At Cycle 4, we calculate m1A and m2A in the step of “Min-sel (A)” and calculate the m1 and m2 in the step of “Min-sel (B)”. Then the operations described in Cycles 4, 5, and 6 are performed. The hardware scheduling for decoding rate-5/6 LDPC codes can be obtained by replacing “Even layer operation” and “Odd layer operation” in FIG. 6 with the 7-cycle CVMU-5/6 operation in FIG. 11. Based on a similar approach, we can configure the CVMU units used in a rate-1/2 LDPC decoder to support rate-2/3 and rate-3/4 LDPC codes.

A decoder based on phase-overlapping message passing decoding (PO-MPD) is proposed in C.-H. Liu, S.-W. Yen, C.-L. Chen, H.-C. Chang, C. Y. Lee, Y.-S. Hsu, and S.-J. Jou, “An LDPC decoder chip based on self-routing network for IEEE 802.16e Applications,” IEEE J. Solid-State Circuits, vol. 43, pp. 684-694, March 2008, which is incorporated here for reference. Let Nᵢ denote the number of iteration. From simulation, we find that EOE-MPD-based decoding with Nit=12 can achieve similar BER as LMPD with Nᵢₜ=15, TPMP with Nᵢₜ=30, and PO-MPD with Nᵢₜ=20. The number of iterations used in calculating throughput is based on similar BER performance. As compared to the decoder in T. Brack, M. Alles, F. Kienle, and N. Wehn, “A synthesizable IP core for WiMAX 802.16e LDPC code decoding,” in Proc. IEEE Annual International Symposium on Personal Indoor and Mobile Radio Communications (PIMRC 2006), Helsinki, Finland, 11-14 Sep. 2006, the parameter of code length (or z) has only a little effect on the throughput of our decoder. In addition, the proposed WiMAX decoder can achieve a throughput higher than the specification of Mobile WiMAX system (30 Mbps) by using a relatively small parallelism and chip area.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A decoding method for low-density parity-check (LDPC) code, comprising steps of:
obtaining a set of parity-check matrices of a set of block codes;
obtaining an identical parity-check matrix from the set of parity-check matrices;
dividing the identical parity-check matrix into an odd identical parity-check matrix and an even identical parity-check matrix, wherein the odd identical parity-check matrix being composed of odd rows of the identical parity-check matrix, and the even identical parity-check matrix being composed of even rows of the identical parity-check matrix; and
decoding the set of block codes basing on the odd identical parity-check matrix and the even identical parity-check matrix.

2. The decoding method of claim 1, wherein the step of decoding the set of block codes basing on the odd identical parity-check matrix and the even identical parity-check matrix comprises:
obtaining a first set of extrinsic values from decoding of the block codes basing on the even identical parity-check matrix, and applying the first set of extrinsic values to decoding of the block codes basing on the odd identical parity-check matrix; and
obtaining a second set of extrinsic values from decoding of the block codes basing on the odd identical parity-check matrix, and applying the second set of extrinsic values to decoding of the block codes basing on the even identical parity-check matrix.

3. The decoding method of claim 2, wherein the set of block codes is decoded basing on the even identical parity-check matrix and the odd identical parity-check matrix, sequentially.

4. The decoding method of claim 3, further dividing an index set of a plurality of variable nodes involving a check node into a first index subset and a second index subset such that the second index subset comprises a part of the variable nodes corresponding to columns of the identical parity-check matrix having weight two, and the first index subset comprises another part of the variable nodes.

5. The decoding method of claim 4, wherein a plurality of code bits, which are indexed by the second index subset, of the set of block codes are decoded basing on both the even identical parity-check matrix and the odd identical parity-check matrix.

6. The decoding method of claim 1, further dividing an index set of a plurality of variable nodes involving a check node into a first index subset and a second index subset such that the second index subset comprises a part of the variable nodes corresponding to columns of the identical parity-check matrix having weight two, and the first index subset comprises another part of the variable nodes.

7. The decoding method of claim 6, wherein the step of decoding the set of block codes basing on the odd identical parity-check matrix and the even identical parity-check matrix comprises:
obtaining a first set of extrinsic values from decoding of the block codes basing on the even identical parity-check matrix, and applying the first set of extrinsic values to decoding of the block codes basing on the odd identical parity-check matrix; and
obtaining a second set of extrinsic values from decoding of the block codes basing on the odd identical parity-check matrix, and applying the second set of extrinsic values to decoding of the block codes basing on the even identical parity-check matrix.

8. The decoding method of claim 7, wherein respectively applying the first set of extrinsic values and the second set of extrinsic values to decoding of the block codes basing on the odd identical parity-check matrix and the even identical parity-check matrix is only performed on a part of the variable nodes, which are indexed by the second index subset, in each of the block codes.

9. The decoding method of claim 1, wherein the block codes are decoded in pipeline.

10. A decoding system for low-density parity-check (LDPC) code, which is adapted to decode LDPC code having a parity-check matrix that is capable of being divided into a plurality of block rows and block columns, and an identical parity-check matrix is obtained from the parity-check matrix and is capable of being divided into an odd identical parity-check matrix and an even identical parity-check matrix, wherein the odd identical parity-check matrix being composed of odd rows of the identical parity-check matrix, and the even identical parity-check matrix being composed of even rows of the identical parity-check matrix, comprises:
a first memory bank, storing a plurality of posterior probability values corresponding to the block columns;
a second memory bank, storing a plurality of check-to-variable messages from a plurality of check nodes to a plurality of variable nodes; and
a processing apparatus, electrically coupled to the first memory bank and the second memory bank to decode a plurality of block codes of the LDPC code basing on the odd identical parity-check matrix and the even identical parity-check matrix.

11. The decoding system of claim 10, wherein the processing apparatus comprises:
a column-to-row module, electrically coupled to the first memory bank for reading at least one of the posterior probability values from the first memory bank and arranging the read posterior probability value into a row-based form;
a check-to-variable message reading module, electrically coupled to the second memory bank for reading the check-to-variable messages;
a check-to-variable message update module, comprising a plurality of check-to-variable message update units and electrically coupled to the column-to-row module and the check-to-variable message reading module for receiving the posterior probability value in row-based form and the read check-to-variable messages, wherein a part of the check-to-variable message update units are used to calculate and output a first set of extrinsic values from one of the variable nodes, which corresponds to one column of the even identical parity-check matrix, to the check nodes, and another part of the check-to-variable message update units are used to calculate and output a second set of extrinsic values from one of the variable nodes, which corresponds to one column of the odd identical parity-check matrix, to the check nodes;
a discrepancy calculating module, electrically coupled to the check-to-variable message update module, the discrepancy calculating module comprising at least one discrepancy calculator unit for calculating a new check-to-variable message and a new row-based form posterior probability value from outputs of the check-to-variable message update module;
a row-to-column module, electrically coupled to the discrepancy calculating module and the first memory bank for arranging the new row-based form posterior probability value into a new posterior probability value suitable to be stored in the first memory bank; and
a check-to-variable message writing module, electrically coupled to the discrepancy calculating module and the second memory bank for receiving the new check-to-variable message and writing the new check-to-variable message to the second memory bank.

12. The decoding system of claim 11, wherein the first memory bank comprises:
a plurality of first memory blocks, each of the first memory blocks stores the posterior probability values corresponding to one of the block columns; and
a plurality of register files, each of the register files comprises at least one register and is used to store the posterior probability values read from the first memory blocks.

13. The decoding system of claim 10, wherein the first memory bank comprises:
a plurality of first memory blocks, each of the first memory blocks stores the posterior probability values corresponding to one of the block columns; and
a plurality of register files, each of the register files comprises at least one register and is used to store the posterior probability values read from the first memory blocks.

14. The decoding system of claim 13, wherein one of the first memory blocks corresponds to one of the register files such that the posterior probability value read from the one of the first memory blocks is stored into the corresponding one of the register files.

15. The decoding system of claim 10, wherein the first memory bank is arranged for pipeline decoding of the block codes, and the pipeline decoding is divided into stages with a predetermined number.

16. The decoding system of claim 15, wherein the first memory bank comprises:
a plurality of first memory blocks, each of the first memory blocks stores the posterior probability values corresponding to one of the block columns; and
a plurality of register files, each of the register files comprises at least the predetermined number of registers and is used to store the posterior probability values read from the first memory blocks.

17. The decoding system of claim 16, wherein each of the first memory blocks is divided into a plurality of memory areas, and when number of the posterior probability values stored in a post memory area, which is one of the memory areas, is less than the predetermined number,
the posterior probability values read from a prior memory area, which is another one of the memory areas and stores the posterior probability values neighbor to the posterior probability values stored in the post memory area, are stored both into the post memory area and a prior register file of the register files; and
output of the prior register file is stored into one of the registers in a post register file of the register files, wherein the post register file receives and stores the posterior probability values read from the post memory area.

18. The decoding system of claim 10, wherein the first memory bank is arranged such that the decoding system is capable of decoding a plurality of LDPC codes having different code rate and code length to each other.

19. The decoding system of claim 18, wherein the first memory bank comprises:
a plurality of first memory blocks, each of the first memory blocks stores the posterior probability values corresponding to only one of the block columns, and each of the first memory blocks is divided into a predetermined number, which is at least the same as a maximum column weight obtained by comparing column weights for all parity-check matrices of the LDPC codes, each of the column weights is for a predetermined block column in one parity-check matrix; and
a plurality of register files, each of the register files comprises at least one register and is used to store the posterior probability values read from the first memory blocks.

20. The decoding system of claim 18, wherein the first memory bank is arranged for pipeline decoding of the block codes, and the pipeline decoding is divided into a predetermined number of stages.

21. The decoding system of claim 20, wherein the first memory bank comprises:
a plurality of first memory blocks, each of the first memory blocks stores the posterior probability values corresponding to only one of the block columns, and each of the first memory blocks is divided into a predetermined number of memory areas, wherein the predetermined number is at least the same as a maximum column weight which is at least the same as a maximum column weight obtained by comparing column weights for all parity-check matrices of the LDPC codes, each of the column weights is for a predetermined block column in one parity-check matrix; and
a plurality of register files, each of the register files comprises at least the predetermined number of registers and is used to store the posterior probability values read from the first memory blocks.

22. The decoding system of claim 21, wherein when number of the posterior probability values stored in a post memory area, which is one of the memory area, is less than the predetermined number,
the posterior probability values read from a prior memory area, which is another one of the memory areas and stores the posterior probability values neighbor to the posterior probability values stored in the post memory area, are stored both into the post memory area and a prior register file of the register files; and
output of the prior register file is stored into one of the registers in a post register file of the register files, wherein the post register file receives and stores the posterior probability values read from the post memory area.
